(19) United States
(12) Patent Application Publication
(10) Pub. No.: US 2026/0244809 A1
(43) Pub. Date: Aug. 20, 2026

(54) REINFORCED GENERATION METHOD FOR HARD-TO-REACH SCENARIOS OF RADIO BLOCK CENTER (RBC) OF TRAIN AUTONOMOUS CIRCULATION AND NAVIGATION (TACN) AND GENERATION SYSTEM THEREOF, AND RBC TEST SYSTEM

(71) Applicant: CASCO SIGNAL LTD., Shanghai (CN)

(72) Inventors: Ming XIA, Shanghai (CN); Jiao Liu, Shanghai (CN); Xiaowei Hou, Shanghai (CN); Jiao Chen, Shanghai (CN); Hao Lai, Shanghai (CN); Lei Feng, Shanghai (CN); Tianhe Wang, Shanghai (CN); Fangyu Zeng, Shanghai (CN)

(73) Assignee: CASCO SIGNAL LTD., Shanghai (CN)

(21) Appl. No.: 19/642,742

(22) Filed: Apr. 9, 2026

Related U.S. Application Data
(63) Continuation-in-part of application No. PCT/CN2024/131290, filed on Nov. 11, 2024.

(30) Foreign Application Priority Data
Sep. 3, 2024 (CN) 202411227661.8

(51) Int. Cl. G06F 30/15; B61L 25/02; B61L 27/60; B61L 27/70; G05D 1/646; G05D 101/15; G05D 109/10; G06N 3/092

(52) U.S. Cl. CPC G06F 30/15; B61L 25/025; B61L 27/60; B61L 27/70; G05D 1/646; G06N 3/092; G05D 2101/15; G05D 2109/10

(57) ABSTRACT

A reinforced generation method for hard-to-reach scenarios of a radio block center (RBC) of train autonomous circulation and navigation (TACN) and a generation system thereof, and an RBC test system are provided. This method models a function of a train operation dynamic system equation as a discrete event dynamic system to describe status transitions of a test environment system. Moreover, this method combines a Q neural network and a target neural network to implement a double deep Q network learning algorithm, thereby constructing a hard-to-reach scenario generator. This method obtains the hard-to-reach scenario generator based on the double deep Q network learning algorithm, which can effectively solve the problem that existing RBC test tools are unable to discover hard-to-reach scenarios, and help improve the test quality and efficiency in testing the capability of the RBC system to cope with the hard-to-reach scenarios.

### CROSS REFERENCE TO THE RELATED APPLICATIONS

This application is a continuation-in-part application of International Application No. PCT/CN2024/131290, filed on Nov. 11, 2024, which is based upon and claims priority to Chinese Patent Application No. 202411227661.8, filed on Sep. 3, 2024, the entire contents of which are incorporated herein by reference.

### TECHNICAL FIELD

The present disclosure relates to the field of train operation control, and in particular, to a reinforced generation method for hard-to-reach scenarios of a radio block center (RBC) of train autonomous circulation and navigation (TACN) and a generation system thereof, and a RBC test system.

### BACKGROUND

In recent years, with the research and development of the new-type train operation control system based on satellite positioning (abbreviated as TACN system), by adopting the multi-source fusion-based train autonomous positioning method and the more secure train integrity checking methods, the limitations of the conventional track circuit have been broken through. Taking the tail of the preceding train as the end of authority (EOA), the speed-distance control mode is adopted, which greatly shortens the train headway and improves the running efficiency.

The radio block center system (abbreviated as RBC) is a typical safety-critical system, which is core ground equipment in the TACN system. The RBC generates control commands sent to the trains according to messages (track section occupation, route statuses, temporary speed restriction, and the like) received from external ground systems (interlocking equipment, a temporary speed restriction server, and the like) and information (train parameters, position reports, and the like) acquired from on-board equipment, and provides movement authority (abbreviated as MA), such that the trains operate safely on lines within an RBC jurisdiction. The functional integrity of the RBC equipment is the key to ensure the safety and efficient operation of the whole system.

The RBC system totally includes more than ten types of operation scenarios from registration activation to parking deregistration. Different operation scenarios involve distinct participants, interactive behaviors and control modes. In addition, there exist complex dynamic switching and superposition relationships between different scenarios. Consequently, the potential hazardous behaviors of the RBC system and causes thereof are characterized by high concealment, diversity and complexity. The quality of automated testing depends on the development of test scripts. However, real-world scenarios are characterized by infinite richness, unpredictability and high uncertainty, resulting in the continuous manifestation of fragility in manually developed test cases during practical scenario applications. Meanwhile, the positions of the trains are from the onboard position reports in the TACN system. However, owing to the potential latency in wireless communication (with a maximum delay time of 60 s), a spatiotemporal hysteresis phenomenon exists between the train position calculated by the RBC and the actual position of the train.

During actual operations, high-risk scenarios that feature a low occurrence probability and are hard to discover in the testing process are called hard-to-reach scenarios. However, it is difficult for the existing RBC test tools to fully detect/generate the above-mentioned various hard-to-reach scenarios, and thus to fully test the response capability of the RBC, which poses considerable challenges to the scheme design and verification of the RBC. Therefore, solving the problems associated with hard-to-reach scenarios with low probabilities and high risks has become a key technical challenge in the testing and verification of the RBC system.

It is to be understood that the foregoing statements merely provide the background art related to the present disclosure and do not necessarily constitute the prior art.

### SUMMARY

Based on the above-mentioned technical problems, an objective of the present disclosure is to provide a reinforced generation method for hard-to-reach scenarios of a radio block center (RBC) of train autonomous circulation and navigation (TACN) and a generation system thereof, and a RBC test system. This method may effectively solve the problem that existing RBC test tools cannot discover the hard-to-reach scenarios, which helps improve the testing quality and efficiency of the RBC test tools in evaluating the capability of the RBC system to respond to the hard-to-reach scenarios.

To achieve the above objective, the present disclosure is implemented by the following technical solutions:

A reinforced generation method for hard-to-reach scenarios of a radio block center (RBC) of train autonomous circulation and navigation (TACN), including the following steps:
S1, constructing a discrete event dynamic system according to environmental status variables of train operation;
S2, constructing a Q neural network and a target neural network by means of a reinforcement learning algorithm;
S3, randomly selecting a group of environmental status variable data as the current environmental status variable Sₜ corresponding to the current time t;
S4, acquiring action information ac corresponding to the current environmental status variable Sₜ by means of the Q neural network;
S5, obtaining a new environmental status variable Sₜ₊₁ corresponding to the next time point t+1 based on the action information ac and the discrete event dynamic system, and calculating a reward value rₜ of the Q neural network based on a reward function R when the action information ac is implemented in an environment, where during the calculation based on the reward function R, the higher the degree of matching between the environmental status variables and the hard-to-reach scenario conditions, the higher the reward value;
S6, inputting the new environmental status variable Sₜ₊₁ into the target neural network to calculate a maximum Q value of the target neural network, and acquiring a reward value yₜ of the target neural network in an Sₜ₊₁ status based on the reward value rₜ of the Q neural network;
S7, calculating a loss function according to the reward value rₜ of the Q neural network, a Q value of the Q neural network, and the maximum Q value of the target neural network, calculating a Q value deviation Δθ between the Q neural network and the target neural network, and updating a network parameter θ of the Q neural network based on the loss function and the Q value deviation Δθ;
S8, determining whether a first preset condition for reaching a terminal status is satisfied; if the first preset condition is not satisfied, determining a second preset condition for updating a target neural network parameter θ⁻ is satisfied; if the second preset condition is satisfied, updating the target neural network parameter θ⁻ and then proceeding to S3; and if the second preset condition is not satisfied, proceeding to S3; and
S9, if the first preset condition is satisfied, terminating training to obtain the hard-to-reach scenario generator of the RBC.

Optionally, the discrete event dynamic system is represented as:

$$y ( t ) = f ( x ( t ) , u ( t ) ) \qquad ( 1 )$$

$$x ( t + 1 ) = g ( x ( t ) , u ( t ) ) , \qquad ( 2 )$$

where x(t) is the current environmental status variable Sₜ corresponding to the current time t, u(t) is a system input quantity, which is the action information ac, y(t) is a system output quantity, f( ) is a processing procedure function, and g( ) is a status transition operation process function;

the status equation corresponding to the discrete event dynamic system is shown in Equation (3) and Equation (4):

$$x ( t + 1 ) = A [ \begin{matrix}sec \\ route \\ traincom \\ trainpos \\ trainMA\end{matrix} ] + B [ u ( t ) ] \qquad ( 3 )$$

$$y ( t ) = C [ x ( t ) , u ( t ) ] , \qquad ( 4 )$$

where x(t+1) is the new environmental status variable Sₜ₊₁ corresponding to the next time point t+1; A is a status matrix of the discrete event dynamic system, configured to reflect a coupling relationship among status variables in the system; B is an input matrix, configured to reflect how the system input quantity affects the status variables; C is an output matrix, indicating a conversion relationship from the status variables to outputs; see represents a section status, route represents a route status, traincom represents a train communication status, trainpos represents a train position status, and trainMA represents a train authority status.

Optionally, the environmental status variables include:
at least one of the section status, the route status, the train communication status, the train position status, and the train authority status.

Optionally, the section status includes an idle status, an occupied status, a cleared status, a train envelope existing status, and a hidden train fault occupied status;
the route status includes normal, shunting, inactive, in use, unavailable, and presence of other trains;
the train communication status includes normal communication, disconnection, registration, deregistration, and delay;
the train position status includes a section, a pre-route position, an approach section, an in-route position, the last section of a route, a post-route position, and preceding train information; and
the train authority status includes the route.

Optionally, in S4, the double deep Q network generates a random number; when the random number is less than a preset value, a route allocation action is randomly selected; and when the random number is greater than or equal to the preset value, the current Q neural network is selected to output the optimal action information ac.

Optionally, the randomly selecting a route allocation action includes:
randomly selecting action information acₜ with a probability ε in the Q neural network, exploring the environment with a probability ε, and selecting the current optimal status with a probability (1−ε), i.e.,

$${ac}_{t} = arg {max}_{ac} Q ( {S}_{t} , ac ; θ ) ,$$

where ε is a greedy probability; where a larger value is used in an early training stage ε to efficiently search for a train operation environment, and the value of ε is gradually reduced as training progress and status continuously transition.

Optionally, an expression of the reward function R is shown in Equation (5):

$$R = {α}_{1} {r}_{1} - {α}_{2} {r}_{2} + {α}_{3} {r}_{3} , \qquad ( 5 )$$

where r₁, r₂, and r₃ are a discovery reward, an exploration failure reward, and an irrational allocation reward, respectively, and α₁, α₂, and α₃ are weight coefficients of the rewards;

the discovery reward is configured to improve an exploration capability of the hard-to-reach scenario generator for the hard-to-reach scenarios, and an expression of the discovery reward is shown in Equation (6):

$${r}_{1} = \{ \begin{matrix}a , & route allocation error \\ 0 , & others\end{matrix} \qquad ( 6 )$$

the exploration failure reward is configured to indicate whether a hard-to-reach scenario occurs within a certain period, and an expression of the exploration failure reward is shown in Equation (7):

$${r}_{2} = \{ \begin{matrix}p , & exploration failure \\ 0 , & exploration success\end{matrix} and \qquad ( 7 )$$

the irrational allocation reward is configured to indicate whether an irrational allocation occurs within a certain period, and an expression of the irrational allocation reward is shown in Equation (8):

$${r}_{3} = \{ \begin{matrix}- q , & irrational allocation \\ q , & rational allocation\end{matrix} . \qquad ( 8 )$$

Optionally, the loss function=the maximum Q value of the target neural network in the Sₜ₊₁ status+the reward value rₜ of the Q neural network in the Sₜ status−the Q value of the Q neural network in the Sₜ status.

Optionally, the Q value deviation Δθ is as follows:

$$Δ θ = α [ {y}_{t} - Q ( {S}_{t} , ac ; θ ) ] ∇ Q ( S , AC ; θ ) ,$$

where α is a deep learning rate, S,AC represent a discrete event dynamic system status set and a set of selected action information, respectively, and yₜ is the reward value of the target neural network in the Sₜ₊₁ status.

Optionally, the reward value yₜ of the target neural network in the Sₜ₊₁ status is as follows:

if the current status Sₜ is a terminal status, yₜ=rₜ, otherwise, yₜ=the maximum Q value of the target neural network in the Sₜ₊₁ status+rₜ, i.e.

$${y}_{t} = {r}_{t} + γ Q ( {S}_{t + 1} , arg {max}_{ac} Q ( {S}_{t} , ac ; θ ) ; {θ}^{-} ) ,$$

where γ is a discount factor.

Optionally, if the Sₜ₊₁ status is not the terminal status, a quadruple {Sₜ, ac, rₜ, Sₜ₊₁} is stored in an experience replay buffer, and the Q neural network selects several quadruples from the experience replay buffer for training; and the target neural network selects several quadruples from the experience replay buffer for training.

Optionally, the updating a target neural network parameter θ⁻ includes:
copying the network parameter θ of the Q neural network to the target neural network to enable θ⁻=θ.

Optionally, the Q neural network is a fully connected network, where a ReLU activation function is adopted among fully connected layers thereof, and the Q neural network provides a bounded output by means of a tanh activation function.

Optionally, the target neural network and the Q neural network are the same in structure.

Optionally, the first preset condition includes:
the number of training iterations reaching a first preset number;
and/or a duration of a training cycle reaching the first preset duration;
and/or a train entering an incorrect route.

Optionally, the second preset condition includes:
the number of training iterations reaching a second preset number.

Optionally, a reinforced generation system for hard-to-reach scenarios of a radio block center (RBC) of train autonomous circulation and navigation (TACN), including:
a hard-to-reach scenario generator generated by adopting the above-mentioned reinforced generation method for the hard-to-reach scenarios of an RBC of TACN; and
a discrete event dynamic system, in communication connection to the hard-to-reach scenario generator.

Optionally, a radio block center (RBC) test system, including:
the hard-to-reach scenario generator generated by adopting the above-mentioned reinforced generation method for hard-to-reach scenarios of an RBC of TACN.

Compared with the prior art, the present disclosure has the following advantages:

In the reinforced generation method for hard-to-reach scenarios of an RBC of TACN and a generation system thereof, and an RBC test system provided by the present disclosure, this method models a function of a train operation dynamic system equation as a discrete event dynamic system to describe status transitions of a test environment system. Moreover, this method combines a Q neural network and a target neural network to implement a double deep Q network learning algorithm, thereby constructing a hard-to-reach scenario generator. This method may effectively explore/generate the hard-to-reach scenarios that may occur in the actual operation, and help improve the test quality and efficiency of the RBC test tools in testing the capability of the RBC system to cope with the hard-to-reach scenarios.

### BRIEF DESCRIPTION OF THE DRAWINGS

FIG. 1 is a schematic diagram of a brief process of a double deep Q network learning algorithm provided by the present disclosure.

FIG. 2 is a schematic diagram of a Q neural network and a target neural network provided by the present disclosure.

FIG. 3 is a schematic diagram of a route allocation scenario of an RBC provided by the present disclosure.

FIGS. 4-6 are schematic diagrams of three route allocation scenarios represented by a discrete event dynamic system in the present disclosure.

FIG. 7 is a schematic diagram of a hidden train route scenario of communication train misallocation searched by a hard-to-reach scenario generator provided by the present disclosure.

FIG. 8 is a schematic diagram of a scenario where a following train is misallocated with the route of a preceding train and searched by a hard-to-reach scenario generator.

FIG. 9 is a schematic diagram of a train operation environment architecture provided by the present disclosure.

### DETAILED DESCRIPTION OF THE EMBODIMENTS

In order to make the objectives, technical solutions and advantages of the embodiments of the present disclosure clearer, the technical solutions in the embodiments of the present disclosure will be clearly and completely described below in conjunction with the accompanying drawings in the embodiments of the present disclosure. Apparently, the described embodiments are part rather than all of the embodiments of the present disclosure. All other embodiments obtained by those of ordinary skill in the art based on the embodiments of the present disclosure without creative efforts shall fall within the protection scope of the present disclosure.

It should be noted that in this document, the terms “comprise”, “include”, “have” or any of their variants are intended to cover non-exclusive inclusion, such that a process, method, article or terminal device that includes a series of elements not only includes those elements, but also includes other elements not explicitly listed, or further includes elements inherent in such process, method, article or terminal device. Without further limitation, elements defined by the phrases “comprising . . . ” or “including . . . ” do not exclude the presence of additional elements in the process, method, article or terminal device that includes the elements.

It should be noted that the accompanying drawings are presented in a highly simplified form and with non-precise proportions, which are only intended to conveniently and clearly assist in illustrating the objectives of the embodiments of the present disclosure.

To solve the problem of low probability and high risk associated with hard-to-reach scenarios in the system testing of the RBC of the TACN, the present disclosure provides a reinforced generation method for hard-to-reach scenarios of a radio block center (RBC) of train autonomous circulation and navigation (TACN). This method is a reinforced generation method for hard-to-reach scenarios based on a discrete event dynamic system (abbreviated as DEDS). On the basis of this method, the hard-to-reach scenario generator may be generated to generate various hard-to-reach scenarios to test the capability of the RBC system to cope with the hard-to-reach scenarios. This method helps improve the capability and testing quality of the RBC test system for quick testing of the RBC.

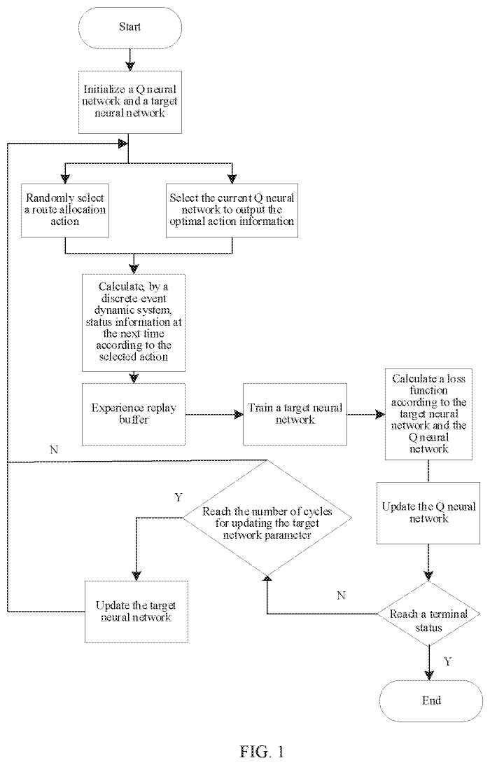

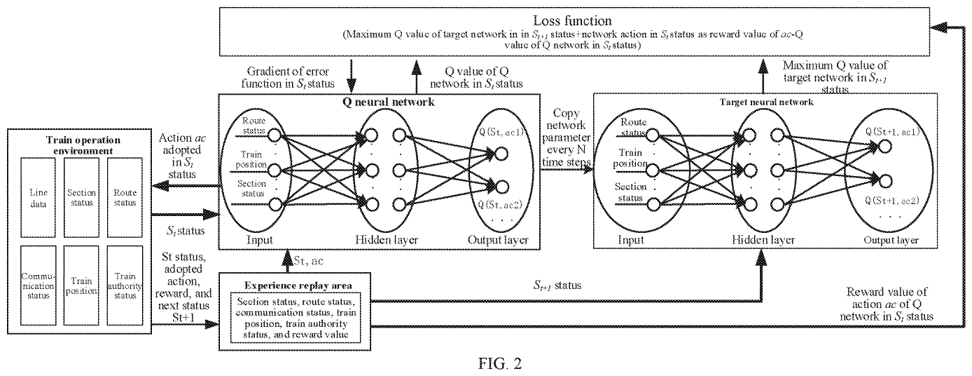

Specifically, as shown in FIG. 1 and FIG. 2, the reinforced generation method for hard-to-reach scenarios of a radio block center (RBC) of train autonomous circulation and navigation (TACN) provided by the present disclosure includes the following steps: S1, a discrete event dynamic system is constructed according to environmental status variables of train operation; S2, a Q neural network and a target neural network are constructed by means of a reinforcement learning algorithm; S3, a group of environmental status variable data are randomly selected as the current environmental status variable Sₜ corresponding to the current time t; S4, action information ac corresponding to the current environmental status variable Sₜ is acquired by means of the Q neural network; S5, a new environmental status variable Sₜ₊₁ corresponding to the next time point t+1 is obtained based on the action information ac and the discrete event dynamic system, and a reward value rₜ of the Q neural network is calculated based on a reward function R when the action information ac is implemented in an environment, where during the calculation based on the reward function R, the higher the degree of matching between the environmental status variables and the hard-to-reach scenario conditions, the higher the reward value; S6, the new environmental status variable Sₜ₊₁ is input into the target neural network to calculate a maximum Q value of the target neural network, and a reward value yₜ of the target neural network in an Sₜ₊₁ status is acquired based on the reward value rₜ of the Q neural network; S7, a loss function is calculated according to the reward value rₜ of the Q neural network, a Q value of the Q neural network, and the maximum Q value of the target neural network, a Q value deviation Δθ between the Q neural network and the target neural network is calculated, and a network parameter θ of the Q neural network is updated based on the loss function and the Q value deviation Δθ; S8, whether a first preset condition for reaching a terminal status is satisfied is determined; if the first preset condition is not satisfied, a second preset condition for updating a target neural network parameter θ⁻ is satisfied is determined; if the second preset condition is satisfied, the target neural network parameter θ⁻ is updated and the step then proceeds to S3; and if the second preset condition is not satisfied, the step proceeds to S3; and S9, if the first preset condition is satisfied, training is terminated to obtain the hard-to-reach scenario generator of the RBC.

It can be known from the above that by combining the RBC train control dynamic system model with the reinforcement learning method, the present disclosure provides the reinforced generation method for hard-to-reach scenarios of the RBC based on the discrete event dynamic system. Owing to the large number and high complexity of scenarios in the train operation system, it is impossible to establish an accurate expression model based on formal derivation. Therefore, this method provided by the present disclosure models a function of a train operation dynamic system equation as a discrete event dynamic system model to describe status transitions of a test environment system. In another aspect, the present disclosure implements the double deep Q network learning algorithm based on the Q neural network and the target neural network, so as to construct the hard-to-reach scenario generator. During training, the hard-to-reach scenario generator acquires the system status from the discrete event dynamic system (environment) and calculates the action information in the current status by the double deep Q network learning algorithm. The discrete event dynamic system converts the system status under the influence of the action information (such as the RBC route allocation) and outputs the action information (scenario) at the next time and the reward value rₜ of the Q neural network corresponding to the action information. The loss function and the Q value deviation Δθ between the Q neural network and the target neural network are obtained based on the double deep Q network learning algorithm, and the network parameter θ of the Q neural network is updated based on the loss function and the Q value deviation Δθ. In this method, the network parameter θ of the Q neural network will be updated in each iteration. The network parameter θ⁻ of the target neural network will be updated after meeting a preset condition, which may effectively guarantee the stability of a search target within a certain time range. The hard-to-reach scenario generator generated based on the above method may effectively solve the problem that existing RBC test tools are unable to discover hard-to-reach scenarios, and help improve the test quality and efficiency of the RBC test tools in testing the capability of the RBC system to cope with the hard-to-reach scenarios.

It can be known from the above that in the present disclosure, modeling and analysis of the RBC train control process are carried out based on the discrete event dynamic system, and the status equation of the discrete event dynamic system is designed. In this embodiment, taking a train movement authority route allocation status of the RBC on train operation control as an example, the hard-to-reach scenarios are searched. In this embodiment, the focus is on the impact of the RBC processing logic on the train operation system. Its action can be set as the RBC assigning a route to the train. Therefore, a status equation of the discrete event dynamic system for the train movement authority route allocation of the RBC is designed. The discrete event dynamic system abstracts the train operation environment into system statuses such as trains, sections and routes. The hard-to-reach scenario generator trained based on the discrete event dynamic system can discover/generate hard-to-reach scenarios (actions) capable of stimulating the RBC system to generate train movement authority route allocation erroneous behaviors.

Specifically, the real train operation scenario is a complex dynamic system that changes over time, featuring the characteristics of unpredictability and inexhaustibility. The line data and control rules in the scenario are static structures that do not change over time and may be generated through a combination approach. On the contrary, the train operation process is a dynamic system that changes over time, with an infinite number of system status combinations, and it is impossible to exhaust all parameter combinations based on the discrete event combination generation method.

The discrete event dynamic system is a dynamic system, the status evolution of which is driven by asynchronous and abrupt events, and the changes in these statuses are caused by the occurrence of various events such as the emergence or disappearance of certain environmental conditions, and the initiation or completion of system operations. The status variable of the discrete event dynamic system is x(t). At any time t, the output y(t) of the system may be calculated and solved by the numerical value x(t) of the status variable at the time t and the input u(t). Specifically, the discrete event dynamic system may be represented as:

$$y ( t ) = f ( x ( t ) , u ( t ) ) \qquad ( 1 )$$

$$x ( t + 1 ) = g ( x ( t ) , u ( t ) ) , \qquad ( 2 )$$

where x(t) is the current environmental status variable Sₜ corresponding to the current time t, u(t) is a system input quantity, which is the action information ac, y(t) is a system output quantity, f( ) is a processing procedure function, and g( ) is a status transition operation process function.

Specifically, when the train operation process is described with the discrete event dynamic system, the system variables x(t), i.e., the environmental status variables, are a group of variables that intactly describe the quantity of the system status. For the RBC train control system, the environmental status variables include a section status, a route status, and a train status. The train status includes at least one of a train communication status, a train position status (an absolute position and relative section positions (a front-end position and a rear-end position)), a train integrity status, and a train authority status. Further, the section status includes an idle status, an occupied status, a cleared status, a train envelope existing status, and a hidden train fault occupied status; the route status includes normal, shunting, inactive, in use, unavailable, and presence of other trains; the train communication status includes normal communication, disconnection, registration, deregistration, and delay; the train position status includes a section, a pre-route position, an approach section, an in-route position, the last section of a route, a post-route position, and preceding train information; and the train authority status includes the route.

The system input quantity u(t) is a major driving force that drives the system status to change dynamically. This embodiment mainly considers the impact of the RBC on train operation control. The input is the processing logic of the RBC, mainly considering whether the route is allocated to the train. y(t) is the system output quantity. The objective of the present disclosure is to search for the hard-to-reach scenarios in the RBC train control scenario by the hard-to-reach scenario generator, so as to test the control logic of the RBC for the hard-to-reach scenarios. Therefore, the system output quantity is selected as the evaluation information of the train control scenario, i.e., the quality of the selected scenario. The more the selected scenario conforms to the characteristics of the hard-to-reach scenario, the higher its evaluation will be. If the RCB mistakenly allocate the route of another train to the train in some scenarios or the route is degraded, the RBC still allocate the route to the train, considering that the evaluation value of this scenario is relatively high. Otherwise, the evaluation value is relatively low. f( ) is a processing procedure stipulated by technical specifications, including section status conversion, route status conversion, train positioning, movement authority calculatable transmission, train-to-ground communication interface specifications, and the like. x(t+1) represents a system status at the next time point. On the basis of the current system status, the status of the next system is obtained according to system input operation.

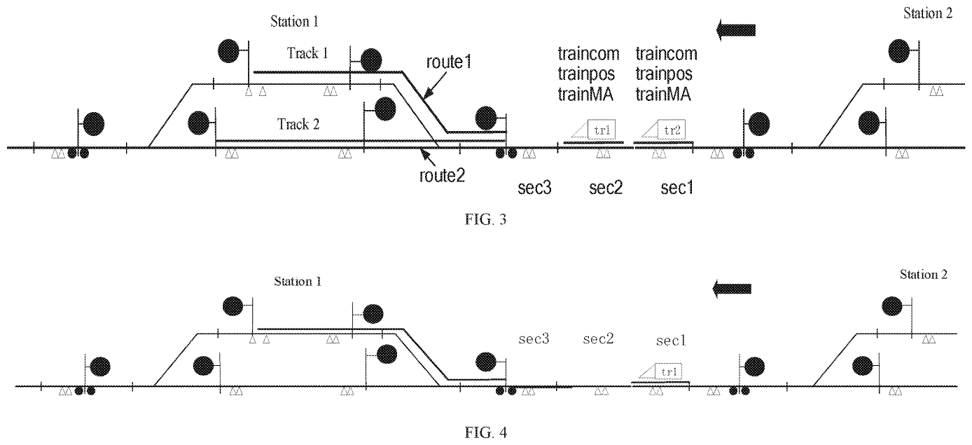

In the TACN system, the RBC is required to calculate the movement authority for the train and may control train operation. On a per-route basis in the station, the RBC calculates the movement authority for the train. A common process is as follows: before the train travels to the route, the route is opened, and the RBC decides whether to authorize the allocation of the route to the train. After the train obtains the route authority and enters the route, the signal is closed and the route status is changed to in use. After the train exits the route, the route is unlocked. The RBC is required to allocate the route according to the positional relationship between the train and the route, so as to control train operation. As shown in FIG. 3, it shows an RBC route allocation scenario parametric model in an embodiment. The environmental status variable x(t) mainly includes x(t)={sec, route, traincom, trainpos, trainMA}, where sec represents the section status, route represents the route status, traincom represents the train communication status, trainpos represents the train position status, and trainMA represents the train authority status.

The block shown in FIG. 3 is composed of 3 sections, where the train 1, i.e., tr1 is in the section 2, the train 2, i.e., tr2 is in the section 1, the train 1 and the train 2 respectively run through the route 1 and the route 2 in accordance with the plan and enter the track 1 and the track 2 of the station 1. The environmental status variables x(t) represent: the section statuses [sec1[occupied], sec2[occupied], sec3[cleared]; the train communication statuses [traincom1[registration], traincom2[registration]; the train position statuses [trainpos1[block], trainpos2[block]]; the train authority status [trainMA1[M3 includes the route], trainMA2[M3 does not include the route]]; the route statuses [route1[normal], route 2[normal]].

The operation path and range of the train are controlled by whether the RBC allocates the route or not. Therefore, the system input is the decision of the RBC on whether to allocate the route, i.e., the action. The main hazards that may arise when the RBC controls train operation by allocating routes are reflected in that incorrectly allocating a non-accessible route or a route with hazard points (other trains) within the authorized scope to a train will lead to hazards such as train derailment or collision with other trains. The non-accessible route includes two levels of meaning: I, the interlocking system determines that the route is non-accessible and sends the result to the RBC via interface information, and IL, the RBC receives the route open status provided by the interlocking system, but determines on its own that the route is non-accessible, for example, when there are other trains on the route. In this embodiment, the hard-to-reach scenario generator is mainly used to search for scenarios where incorrect routes may be allocated to trains. Therefore, the system output quantity is whether an incorrect route has been allocated.

Based on the above, a status equation for RBC movement authority route allocation, i.e., the status equation corresponding to the discrete event dynamic system is shown in Equation (3) and Equation (4):

$$x ( t + 1 ) = A [ \begin{matrix}sec \\ route \\ traincom \\ trainpos \\ trainMA\end{matrix} ] + B [ u ( t ) ] \qquad ( 3 )$$

$$y ( t ) = C [ x ( t ) , u ( t ) ] , \qquad ( 4 )$$

where x(t+1) is the new environmental status variable Sₜ₊₁ corresponding to the next time point t+1; A is a status matrix of the discrete event dynamic system, configured to reflect a coupling relationship among status variables in the system, for example, when the train is in a route approach section, the approach section status is an occupied status, the route status is a normal status, and the route signal is open; B is an input matrix, configured to reflect how the system input quantity affects the status variables, for example, the RBC determines the route to be available and allocates the route to the train; C is an output matrix, indicating a conversion relationship from the status variables to outputs, for example, this status and the RBC decision are incorporated into the train operation environment for scenario evaluation; sec represents the section status, route represents the route status, traincom represents a train communication status, trainpos represents a train position status, and trainMA represents a train authority status.

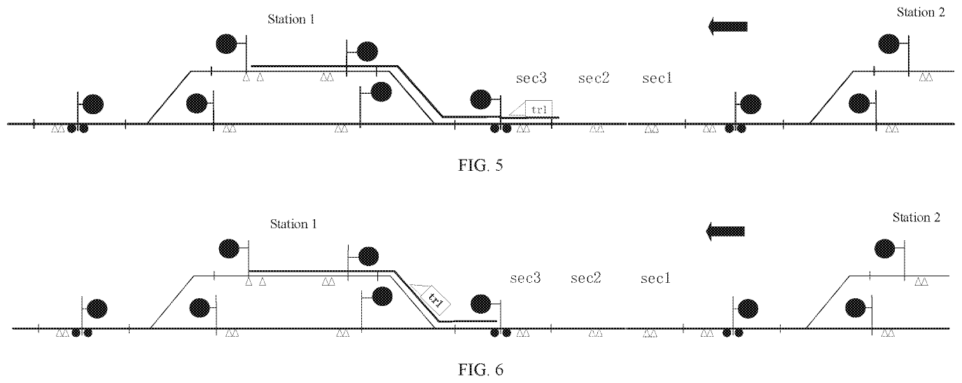

FIGS. 4-6 show three route allocation scenarios represented by the discrete event dynamic system, i.e., examples of three input status data for the neural networks. As shown in FIG. 4, when the train is running in the section (not in the approach section), the route of the forward station is open, and there is no communication-equipped train in the section ahead of the train, but a protection zone for non-communication-equipped trains exists. In this embodiment, the status variables are x₁=[sec₁, sec₂, sec₃], x₂=route₁, x₃=traincom₁, x₄=trainpos₁, x₅=trainMA₁, and the input variable is u. As shown in FIG. 5, the train is in the route approach section, the route is open, and there are neither communication-equipped trains nor non-communication-equipped trains ahead of the train. The status variables are x₁=[sec₃], x₂=route₁, x₃=traincom₁, x₄=trainpos₁, x₅=trainMA₁, and the input variable is u. As shown in FIG. 6, the train is on the route, the route signal is closed, and there are neither communication-equipped trains nor non-communication-equipped trains on the route. The status variables are x₂=route₁, x₃=traincom₁, x₄=trainpos₁, x₅=trainMA₁, and the input variable is u.

In the selection of the status variables for the scenario of train movement authority route allocation, in addition to considering the status of the section ahead of the train and the status of the route, special attention shall also be paid to the positional relationship between the train and the route as well as the train authority status. In addition, the route allocation decision is not isolated. Instead, it shall be determined in conjunction with the dynamic status transitions of the system in continuous time and space, so as to avoid the incorrect allocation of routes to trains and the consequent occurrence of hazards.

Due to the existence of various combinations of sections, routes and the positional relationship between trains and routes, it is difficult to provide a clear system status matrix A. At present, in scenario design, manual analysis and compilation by research and development personnel and testing personnel are mostly adopted, making it difficult to achieve full coverage. In considering the powerful black-box modeling capability of neural networks, this research constructs the hard-to-reach scenario generator based on the double deep Q neural network and achieves mapping relationship modeling from the input u(t) to the output y(t) in the status x(t) by means of the neural network. The model structure of the generated hard-to-reach scenario generator is a neural network, and in during the entire training process, the network weights that meet the requirements will be saved to the hard-to-reach scenario library.

The following is a detailed description of constructing the hard-to-reach scenario generator based on the double deep Q network algorithm to search for hard-to-reach scenarios.

The dynamic interaction process between the RBC route allocation processing logic and the train operation system satisfies the Markov property. The hard-to-reach scenario generation modeling problem may be constructed as the Markov decision process (MDP). By combining the Q learning algorithm with the depth neural network, the present disclosure effectively solves the decision-making problems with a huge solution space. The double deep Q network is an improved deep Q learning algorithm. The present disclosure performs route allocation selection and route allocation evaluation respectively by using two independent networks (the Q neural network and the target neural network are combined to form the double deep Q network). By using the Q neural network as a function approximator for action selection, the selected action is evaluated through the target neural network, which may effectively solve the problem of Q value overestimation that may arise during the learning process of deep Q network.

In this embodiment, the input of the Q neural network is the system status, and the output is the Q value corresponding to the route allocation/non-allocation action for the system state. In considering the scale of the input variable space of the system status, a simple and efficient fully connected network is selected for the research, i.e., the Q neural network is the fully connected network. It can fully mine the hidden rules behind the scenario information from the status, and on the premise of meeting the task requirements, it can also improve the training speed. To improve the convergence speed of the model, a ReLU activation function is used between the fully connected layers of the Q neural network. Finally, linear scaling and bias are performed on the output through the scaling layer. The tanh activation function is adopted herein to provide bounded outputs for route allocation decisions. In this embodiment, the target neural network is the same as the Q neural network in structure. The structures of the target neural network and the Q neural network are as follows: The number of neurons in the input layer is 218 (120 section statuses+8 route statuses+30*3 statuses of vehicles (communication, locations, and MA)); the number of neurons in the hidden layer is 872; and the number of neuron in the output layer is 1.

As shown in FIG. 1 and FIG. 2, as described in Steps S2 to S9 above, the present disclosure generates the RBC hard-to-reach scenario generator, i.e., an agent, by adopting the double deep Q network. In short, the Q neural network and the target neural network are initialized first, the Q neural network parameter θ is initialized, and the target neural network parameter θ⁻ is set to be 0. The agent acquires the current environmental status variable Sₜ from the environment, calculates the action information ac (whether to allocate the routes) corresponding to the agent through the Q neural network, then implements the action information ac to obtain the new environmental status variable Sₜ₊₁, acquires the reward rₜ based on the reward function, and stores the new quadruple {Sₜ, ac, rₜ, Sₜ₊₁} composed of the above elements in the experience replay buffer. Sₜ and ac are acquired from the experience replay buffer and input into the Q neural network to obtain the corresponding Q value Q(Sₜ, ac; θ). Sₜ₊₁ is input into the target neural network to obtain the maximum Q value

$$arg {max}_{ac} Q ( {S}_{t} , ac ; θ ) ,$$

the loss

$$function = {r}_{t} + γ Q ( {S}_{t + 1} , arg {max}_{ac} Q ( {S}_{t} , ac ; θ ) ; {θ}^{-} ) - Q ( {S}_{t} , ac ; θ )$$

is calculated, and the Q value deviation Δθ between the Q neural network and the target neural network is calculated, and based on the loss function and the Q value deviation Δθ, the parameter θ of the Q neutral network is updated through neural network backpropagation. It can be seen from above that in the present disclosure, the target neural network parameter θ⁻ is not updated at each calculation step; instead, the Q neutral network parameter θ is copied to the target neural network only every several steps. This is to ensure the stability of network training, prevent the divergence of Q value estimation, and continuously update the strategy by means of the closed-loop structure.

In the present disclosure, there are two modes of generating the action information ac corresponding to the current environmental status variable Sₜ. Specifically, in S4, the double deep Q network generates a random number. When the random number is less than a preset value, a route allocation action is randomly selected; and when the random number is greater than or equal to the preset value, the current Q neural network is selected to output the optimal action information ac.

Specifically, the randomly selecting a route allocation action includes: action information acₜ is randomly selected with a probability ε in the Q neural network, the environment is searched with a probability ε, and the current optimal status with a probability (1−ε) (an allocation action with the maximum reward value), i.e.,

$${ac}_{t} = arg {max}_{ac} Q ( {S}_{t} , ac ; θ ) ,$$

is selected, where ε is a greedy probability, Sₜ=(secₜ, routeₜ, traincomₜ, trainposₜ, trainMAₜ). where a larger value is used in an early training stage ε to efficiently search for a train operation environment, and the value of ε is gradually reduced as training progress and status continuously transition, to improve the utilization efficiency of the training data. In this embodiment, the initial value of ε is 0.8, and then decreases successively.

Based on the above, according to the selected route allocation action, by combining the environmental status information such as the train position, the route status, and the section status, the discrete event dynamic system environment calculates the train position, the section status, and the train authority status at the next time to obtain the next system status, i.e., the new environmental status variable Sₜ₊₁. The reward value rₜ corresponding to the selected action is determined by a calculation module, and rₜ is determined by a reward function. After calculation, if the new environmental status variable Sₜ₊₁ is not the terminal status, the quadruple {Sₜ, ac, rₜ, Sₜ₊₁} is stored in the experience replay buffer, such that the Q neural network and the target neural network select several quadruple data from the experience replay buffer for training. When the Q value corresponding to the Q neural network is calculated, Sₜ and ac may be acquired from the experience replay buffer and input into the Q neural network to obtain the corresponding Q value Q(Sₜ, ac; θ).

The reward function is an important component of reinforcement learning. Its design directly affects the learning and evolution direction of the agent, i.e., the hard-to-reach scenario generator. Therefore, the reward function is the key to the successful training of the reinforcement learning algorithm. To enable the hard-to-reach scenario generator to generate hard-to-reach scenarios that balance harmfulness and rationality, the present disclosure designs a reward function from two aspects: a discovery reward and an irrational allocation reward. The discovery reward is to improve the capability of the hard-to-reach scenario generator to explore the hard-to-reach scenarios. The irrational allocation reward is to constrain the compliance of the actions of the hard-to-reach scenario generator and improve the rationality of the generated scenarios. In this embodiment, an expression of the reward function R is shown in Equation (5):

$$R = {α}_{1} {r}_{1} - {α}_{2} {r}_{2} + {α}_{3} {r}_{3} , \qquad ( 5 )$$

r₁, r₂ and r₃ are a discovery reward, an exploration failure reward, and an irrational allocation reward, respectively, and α₁, α₂ and α₃ are weight coefficients of the rewards. Final values may be acquired through simulation parameter tuning. In this embodiment, values of α₁, α₂ and α₃ are 0.5, 0.3 and 0.2, respectively.

Specifically, the discovery reward is configured to improve the capability of the hard-to-reach scenario generator to explore the hard-to-reach scenarios. For example, the RBC incorrectly allocates a route to a train, which may cause the train to erroneously enter the route of another train, thereby triggering an emergency stop, derailment, or collision with another train and resulting in hazards, indicating that this scenario meets the conditions of a hard-to-reach scenario. Therefore, the route allocation error may quantify the discovery reward of the hard-to-reach scenario generator. An expression of the discovery reward is shown in Equation (6):

$${r}_{1} = \{ \begin{matrix}a , & route allocation error \\ 0 , & others\end{matrix} , \qquad ( 6 )$$

where the exploration failure reward is configured to indicate whether a hard-to-reach scenario occurs within a certain period. If the hard-to-reach scenario generator has no route allocation error within a certain period, the hard-to-reach scenario generator fails to explore, and a negative reward is given, indicating an exploration failure. An expression of the exploration failure reward is shown in Equation (7):

$${r}_{2} = \{ \begin{matrix}p , & exploration failure \\ 0 , & exploration success\end{matrix} . \qquad ( 7 )$$

Although the present disclosure encourages the occurrence of scenarios involving incorrect allocation, it focuses more on collision accidents caused by the failure of the processing logic of the RBC. Therefore, it is necessary to reduce collision accidents arising from the unreasonable processing logic of the RBC. For example, the route status sent by the interlocking system is unavailable, but the route is still insistently allocated to the train. These unreasonable route allocation scenarios shall guide the exploration direction of the hard-to-reach scenario generator through the reward function, so as to reduce the generation of such scenarios. In this embodiment, the irrational allocation reward is configured to indicate whether an irrational allocation occurs within a certain period. An expression of the irrational allocation reward is shown in Equation (8):

$${r}_{3} = \{ \begin{matrix}- q , & irrational allocation \\ q , & rational allocation\end{matrix} . \qquad ( 8 )$$

a, p, and q are constants, and a specific value may be selected through a simulation parameter.

In another aspect, in S6, several groups of quadruples {Sₜ, ac, rₜ, Sₜ₊₁} may be randomly extracted from the experience replay buffer to train the target neural network, and the new environmental status variable Sₜ₊₁ is input into the target neural network to calculate a target allocation action and a corresponding reward yₜ. In this embodiment, the reward value yₜ of the target neural network in the Sₜ₊₁ status is calculated by the calculation module. If the current environmental status variable Sₜ is the terminal status, yₜ=rₜ. Otherwise, yₜ=the maximum Q value of the target neural network in the Sₜ₊₁ status+rₜ, i.e.,

$${y}_{t} = {r}_{t} + γ Q ( {S}_{t + 1} , arg {max}_{ac} Q ( {S}_{t} , ac ; θ ) ; {θ}^{-} ) ,$$

where γ is a discount factor.

Further, in S7, a loss function is calculated according to the reward value rₜ of the Q neural network, a Q value of the Q neural network, and the maximum Q value of the target neural network, where the loss function is a deviation between two network evaluation functions, and configured to motivate the neural network to converge toward the target network. The loss function=the maximum Q value of the target neural network in the Sₜ₊₁ status+rₜ−the Q value of the Q neural network in the Sₜ status, i.e., the loss function is:

$${r}_{t} + γ Q ( {S}_{t + 1} , arg {max}_{ac} Q ( {S}_{t} , ac ; θ ) ; {θ}^{-} ) - Q ( {S}_{t} , ac ; θ ) .$$

The Q value deviation Δθ between the Q neural network and the target neural network is:

$$Δ θ = α ⌈ {y}_{t} - Q ( {S}_{t} , ac ; θ ) ] ∇ Q ( S , AC ; θ ) ,$$

where α is a deep learning rate, S,AC represent a discrete event dynamic system status set and a set of selected action information, respectively, and yₜ is the reward value of the target neural network in the Sₜ₊₁ status.

Based on the above reinforced learning algorithm, the hard-to-reach scenario generator is trained. As described in S8 and S9, the target neural network parameter θ⁻ is updated after a specified number of steps. It exits if the number of iterations is reached; otherwise, it returns to step S3.

In this embodiment, the updating the target neural network parameter θ⁻ includes: copying the network parameter θ of the Q neural network to the target neural network to enable θ⁻=θ.

Further, the first preset condition includes: the number of training iterations reaching a first preset number; and/or a duration of a training cycle reaching the first preset duration; and/or a train entering an incorrect route.

Exemplarily, in an embodiment, the standard line data of the RBC are adopted as the train operation environment, and a bidirectional (up and down) train operation plan is formulated for the cyclic operation of a total of 30 pairs of trains. The specific correspondence between routes and trains has been determined, which is configured to evaluate whether the route allocation of the RBC meets the expectations. The train-to-ground communication cycle is 6 s, the communication interruption duration is 60 s, and the automatic route triggering mode is adopted for route setting for trains. Fault conditions such as train-to-ground communication timeout, faulty occupation of sections, sectional unlocking of routes, and switch indication loss of routes are introduced. The introduction of these faults is intended to simulate the actual train operation process as closely as possible and facilitate the search for more edge scenarios. In the training process, the cycle of each training, namely a first preset duration, is 1440 min, the sampling step size is 30 min, and the first preset number of times, namely the maximum number of training iterations is 5,000 (a time scale is set to improve the search speed and thus enhance the training efficiency). The training is realized by repeatedly setting train operations in the train operation environment for control purposes. The training cycle and the number of training iterations are also realized through the repeated operation of the operation environment, where the statuses and indicators are input to the controller, and the controller outputs route allocation decisions based on the input statuses, thereby affecting the status transitions of the train operation environment. For each training, the training shall be terminated and new training shall be initiated when a train enters an incorrect route, the training duration exceeds 1,440 min, or the number of training iterations reaches 5,000 (i.e., the preset number of iterations is attained). Further, the reinforced generation method for hard-to-reach scenarios of a radio block center (RBC) of train autonomous circulation and navigation (TACN) has relatively high operational efficiency. By setting a time scale, the method performs 5,000 training iterations with a total time consumption of 11 h; by contrast, the conventional testing method requires manual operation by three testers and takes at least three months.

Further, the second preset condition includes:
the number of training iterations reaching a second preset number. That is, after a certain number of training cycles are reached, the network parameters are synchronized to the target neural network to ensure the stability of the search target within a specific time range. In an embodiment, the second preset number is less than the first preset number.

It should be noted that the objective of the hard-to-reach scenario generator trained by the present disclosure is not to discover/generate the most dangerous hard-to-reach scenarios, but to discover/generate as many hard-to-reach scenarios as possible, which is different from the application of reinforcement learning in the field of optimization and solution. As can be seen from the optimal solution-seeking characteristic of reinforcement learning, the scenarios obtained by continued training are all homogeneous, which cannot improve the diversity of scenarios. Therefore, when the reinforcement learning training of the present disclosure converges, the diversity of generated scenarios is improved by enhancing the exploration capability of the model. In actual applications, a dynamic exploration coefficient (which may be reflected in: 1) dynamically adjusting the reward function weight) and 2) dynamically adjusting the training period, the sampling time, and the like) may be introduced to improve the diversity of the scenarios generated by the hard-to-reach scenario generator. The advantages of this method in terms of dynamic interactive game are illustrated below by means of two specific test scenarios searched and obtained during the training process.

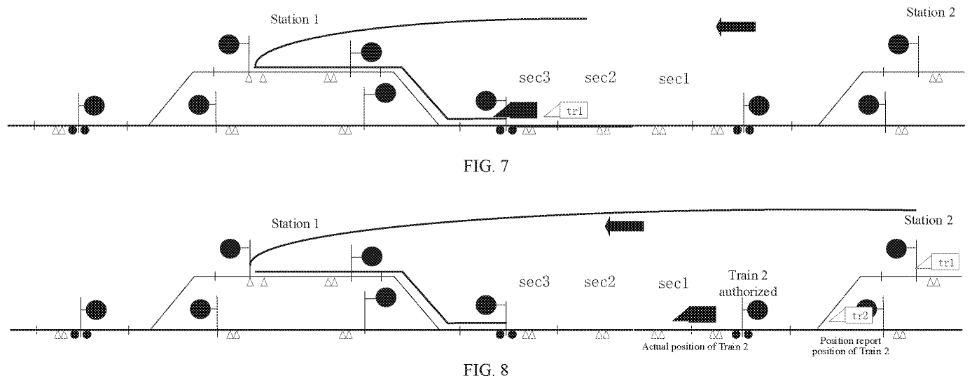

As shown in FIG. 7, in an embodiment, the estimated front end of the train is in the approach section, the train is not authorized, a protection zone exists in the approach section, the forward route is open, and a hidden train exists between the front end of the train and the route signal (the hidden train refers to a train not registered with the RBC system, and the RBC system cannot sense its specific position). The hidden train drives into the first section of the route, and the route status is changed to being used. If the route is allocated to the train at this time, the principle of route-based block operation within the station is violated. The following train is authorized to overrun the preceding train, resulting in the risk of a train collision.

As shown in FIG. 8, in another embodiment, two trains are ready for departure on different tracks. The preceding train reports the current position to the RBC after driving into the route switch section, and subsequently, the preceding train experiences a communication failure and fails to send a position report to the RBC, even though it has actually entered the section. If a departure route to the same section is allocated to the train in another track, the following train (tr1) will be authorized to overrun the tail of the preceding train, resulting in a rear-end collision.

When the RBC system allocates routes for the train, an aggressive strategy can ensure the efficiency of train operation but may introduce potential safety hazards, whereas an overly conservative strategy can guarantee safety at the expense of operational efficiency. The above scenarios serve as an excellent test of the comprehensive decision-making capability of the RBC system in route allocation, and provide an effective testing method for the trade-off decision-making between efficiency optimization and safety optimization. The route allocation scenarios searched by this method can enhance the testing of the safety and usability of route allocation, which are consistent with the actual testing requirements. It indicates that the hard-to-reach test scenario controller constructed based on double deep Q learning algorithm provided by the present disclosure provides an effective path to solve the problem that existing RBC testing software is low in generation efficiency and incomplete scenario coverage.

It is indicated by the simulation test result that the hard-to-reach scenario generator generated by this method can effectively improve the simulation of dynamic game of reliability and availability of the hard-to-reach scenarios, the scenario coverage rate, and the repeatable testing capability.

It should be noted that a scenario search framework of the hard-to-reach scenario generator generated by the reinforced generation method for hard-to-reach scenarios of an RBC of TACN is universal, which is not limited to the route allocation problem, but may also be expanded to aspects such as non-communication train and hidden train protection, and train sequencing, so as to improve the quality of the RBC system test, thereby improving the design quality of the RBC system. In other embodiments, the train operation status equation in the above technical solution is the status equation corresponding to the discrete event dynamic system. Other necessary elements and status conversion process required by the train control system design may be described in detail to provide a support tool for the RBC system design. The double deep Q learning algorithm in the above technical solution may uninterruptedly execute a learning search task without being supervised, to save the designer working hours and optimize the hard-to-reach scenario generator, thereby improving the design quality of the RBC system.

Based on the same inventive concept, the present disclosure further provides a generation system for hard-to-reach test scenarios of an RBC of TACN. This system includes: the hard-to-reach scenario generator generated by using the reinforced generation method for hard-to-reach scenarios of an RBC of TACN, and a discrete event dynamic system. The discrete event dynamic system is in communication connection to the hard-to-reach scenario generator to train the hard-to-reach scenario generator. Based on the hard-to-reach scenario generator and the discrete event dynamic system, the generation system for hard-to-reach test scenarios of an RBC of TACN has the advantage of repeatability. The searched hard-to-reach scenarios can all be stored in a test scenario library, i.e., a hard-to-reach scenario library, such that the hard-to-reach scenarios may be directly applied to a system testing link to verify whether the RBC system has the capability of coping with the hard-to-reach scenarios after function upgrade.

Further, the discrete event dynamic system may be regarded as the train operation environment. The hard-to-reach scenario generator performs intelligent decision-making by means of the double deep Q network (DDQN) algorithm according to real-time status data (such as track occupation, signal status, train position, and speed) according to the train operation environment to output the optimal train route allocation strategy (the optimum refers to the scenario that is most consistent with hard-to-reach conditions). The train operation environment updates the system status according to the strategy output by the controller and feeds the reward evaluation to realize a continuous optimized search process, aiming at improving the hard-to-reach scenario search and generation efficiency of the hard-to-reach scenario generator.

Exemplarily, taking the train receiving process shown in FIG. 1 as an example, the operating principle of the route allocation method based on the reinforced learning principle is described. When the current environmental status variable Sₜ is the Sₜ status, the section status [sec1[normally occupied], sec2[normally occupied], sec3[idle]]; the train communication status [train1[normally communicate], train2[normally communicate]]; the train position status[train1[the train is in front of the route], train2[the train is in front of the route]]; the train authority status [train1[M3 does not include the route], train2[M3 does not include the route]]; the route status [route1[normal, no other trains], route2[inactivated, no other trains]].

The hard-to-reach scenario generator selects the next action: allow route1 for train1 according to a Q network decision-making rule π(a|s). The next status Sₜ₊₁ is as follows: the train authority status [train1[M3 includes route1], train2[M3 does not include the route]]. The conversion of the section statuses is driven by the information collected from trains and track circuits; the train communication status is decided by the communication condition; and the route status conversion is driven according to the process that the train drives into the route. To search for more hard-to-reach scenarios, random occupation and clearing may be increased in the section status to simulate fault occupation and poor shunting of the section; and a random communication delay is increased in the train communication status to simulate the deviation between the actual position of the train and the position report. At the same time, sectional unlocking of the route, a switch indication loss of the route, other trains, and the like are randomly increased in the route status.

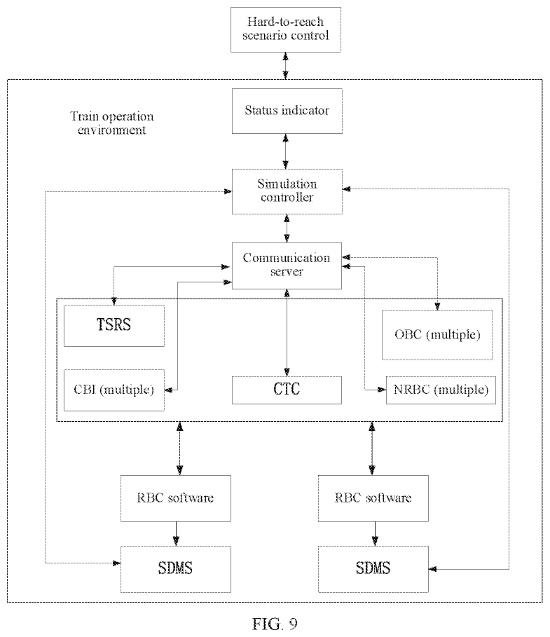

As shown in FIG. 9, the train operation environment is composed of a status indicator, an RBC simulation controller, a communication server, a TSRS simulator (a temporary speed restriction simulator), an OBC (onboard simulator), an NRBC simulator, a CBI simulator, RBC software, and an SDMS (maintenance station software). The status indicator is responsible for extracting the system status from the RBC simulation controller, and transfers the route allocation strategy, i.e., the action information ac generated by the hard-to-reach scenario generator to the RBC software to execute (the generated decision needs to be input to the environment), so as to further evaluate the decision; and the RBC simulation controller is responsible for editing and managing the train operation sequence, and sending the same to the OBC simulator, the TSRS simulator, the CBI simulator, the CTC simulator, and adjacent RBC software to execute. The communication server is set to be responsible for forwarding messages of the RBC simulation controller and receiving the message of an externally disposed simulator and sending the same to the RBC simulation controller. The onboard simulator, the temporary speed restriction simulator, the TSRS simulator, and the adjacent RBC software may all be in communication with a lower computer RBC (real equipment) for assisting in simulating the response actions of the train operation control system. The simulation controller acquires the train operation result by the maintenance station software SDMS and the status indicator converts the train operation result into status information and evaluation results identified by the hard-to-reach scenario generator. The status and decision are executed in the train operation environment. The decision is evaluated according to the set evaluation index, the Q neural network parameter is updated, and the Q neural network parameter is urged to make a decision according to a set target. The above process is repeated till the number of iterations or the convergence requirement is met.

Based on the same inventive concept, the present disclosure further provides an RBC test system. This system includes the hard-to-reach scenario generator generated by using the reinforced generation method for hard-to-reach scenarios of an RBC of TACN. In actual applications, this RBC test system may generate various hard-to-reach scenarios based on the hard-to-reach scenario generator to train and test the RBC system, so as to improve the test accuracy in testing the capability of the RBC system to cope with the hard-to-reach scenarios. In existing RBC test tool software, test cases are manually compiled, with a low probability of generating or discovering hard-to-reach scenarios and great difficulty in doing so. By taking the existing RBC test tool software as an example, a total of three hard-to-reach scenarios are discovered during the 6-month test period; in the RBC testing system provided by the present disclosure, four hard-to-reach scenarios are discovered within two weeks of operation. Therefore, the RBC test system provided by the present disclosure may effectively solve the problem that existing RBC test tools are unable to discover hard-to-reach scenarios, and improves the software testing quality and efficiency.

To sum up, in the reinforced generation method for hard-to-reach scenarios of a radio block center (RBC) of train autonomous circulation and navigation (TACN) and a generation system thereof, and an RBC test system provided by the present disclosure, this method models a function of a train operation dynamic system equation as a discrete event dynamic system to describe status transitions of a test environment system. Moreover, this method combines a Q neural network and a target neural network to implement a double deep Q network learning algorithm, thereby constructing a hard-to-reach scenario generator. This method may effectively search for/generate the hard-to-reach scenarios that may occur in the actual operation, and help improve the test quality and efficiency of the RBC test tools in testing the capability of the RBC system to cope with the hard-to-reach scenarios.

Although the content of the present disclosure has been described in detail through the above-mentioned preferred embodiments, it should be understood that the above description shall not be deemed as a limitation to the present disclosure. After those skilled in the art reads the above content, various modifications and substitutions to the present disclosure will become apparent. Therefore, the scope of protection of the present disclosure shall be defined by the appended claims.

What is claimed is:

1. A reinforced generation method for hard-to-reach scenarios of a radio block center (RBC) of train autonomous circulation and navigation (TACN), comprising:
S1, constructing a discrete event dynamic system according to environmental status variables of train operation;
S2, constructing a Q neural network and a target neural network by a reinforcement learning algorithm;
S3, randomly selecting a group of environmental status variable data as a current environmental status variable Sₜ corresponding to a current time t;
S4, acquiring action information ac corresponding to the current environmental status variable Sₜ by the Q neural network;
S5, obtaining a new environmental status variable Sₜ₊₁ corresponding to a next time point t+1 based on the action information ac and the discrete event dynamic system, and calculating a reward value rₜ of the Q neural network based on a reward function R when the action information ac is implemented in an environment, wherein during the calculation based on the reward function R, the higher a degree of matching between the environmental status variables and hard-to-reach scenario conditions, the higher the reward value;
S6, inputting the new environmental status variable Sₜ₊₁ into the target neural network to calculate a maximum Q value of the target neural network, and acquiring a reward value yₜ of the target neural network in an Sₜ₊₁ status based on the reward value rₜ of the Q neural network;
S7, calculating a loss function according to the reward value rₜ of the Q neural network, a Q value of the Q neural network, and the maximum Q value of the target neural network, calculating a Q value deviation Δθ between the Q neural network and the target neural network, and updating a network parameter θ of the Q neural network based on the loss function and the Q value deviation Δθ;
S8, determining whether a first preset condition for reaching a terminal status is satisfied; if the first preset condition is not satisfied, determining a second preset condition for updating a target neural network parameter θ⁻ is satisfied; if the second preset condition is satisfied, updating the target neural network parameter θ⁻ and then proceeding to S3; and if the second preset condition is not satisfied, proceeding to S3; and
S9, if the first preset condition is satisfied, terminating training to obtain a hard-to-reach scenario generator of the RBC, wherein the first preset condition and the second preset condition are dynamically adjusted to dynamically adjust a training period.

2. The reinforced generation method for the hard-to-reach scenarios of the RBC of TACN according to claim 1, wherein the discrete event dynamic system is represented as:
$$y ( t ) = f ( x ( t ) , u ( t ) ) \qquad ( 1 )$$
$$x ( t + 1 ) = g ( x ( t ) , u ( t ) ) , \qquad ( 2 )$$
wherein x(t) is the current environmental status variable Sₜ corresponding to the current time t, u(t) is a system input quantity and the action information ac, y(t) is a system output quantity, f( ) is a processing procedure function, and g( ) is a status transition operation process function;
a status equation corresponding to the discrete event dynamic system is shown in Equation (3) and Equation (4):
$$x ( t + 1 ) = A [ \begin{matrix}sec \\ route \\ traincom trainpos \\ trainMA\end{matrix} ] + B [ u ( t ) ] \qquad ( 3 )$$
$$y ( t ) = C [ x ( t ) , u ( t ) ] , \qquad ( 4 )$$
wherein x(t+1) is the new environmental status variable Sₜ₊₁ corresponding to the next time point t+1; A is a status matrix of the discrete event dynamic system, configured to reflect a coupling relationship among status variables in the discrete event dynamic system; B is an input matrix, configured to reflect how the system input quantity affects the status variables; C is an output matrix, indicating a conversion relationship from the status variables to outputs; sec represents a section status, route represents a route status, traincom represents a train communication status, trainpos represents a train position status, and trainMA represents a train authority status.

3. The reinforced generation method for the hard-to-reach scenarios of the RBC of TACN according to claim 1, wherein the environmental status variables comprise:
at least one of a section status, a route status, a train communication status, a train position status, and a train authority status.

4. The reinforced generation method for the hard-to-reach scenarios of the RBC of TACN according to claim 3, wherein
the section status comprises an idle status, an occupied status, a cleared status, a train envelope existing status, and a hidden train fault occupied status;
the route status comprise normal, shunting, inactive, in use, unavailable, and presence of other trains;
the train communication status comprises normal communication, disconnection, registration, deregistration, and delay;
the train position status comprises a section, a pre-route position, an approach section, an in-route position, a last section of a route, a post-route position, and preceding train information; and
the train authority status comprises the route.

5. The reinforced generation method for the hard-to-reach scenarios of the RBC of TACN according to claim 1, wherein
in S4, a double deep Q network generates a random number; when the random number is less than a preset value, a route allocation action is randomly selected; and when the random number is greater than or equal to the preset value, the current Q neural network is selected to output the optimal action information ac.

6. The reinforced generation method for the hard-to-reach scenarios of the RBC of TACN according to claim 5, wherein the randomly selecting the route allocation action comprises:
randomly selecting action information acₜ with a probability ε in the Q neural network, exploring the environment with the probability ε, and selecting a current optimal status with a probability (1−ε), i.e.,
$${ac}_{t} = arg {max}_{ac} Q ( {S}_{t} , ac ; θ ) ,$$
wherein ε is a greedy probability; wherein a larger value is used in an early training stage ε to efficiently search for a train operation environment, and a value of ε is gradually reduced as training progress and status continuously transition.

7. The reinforced generation method for the hard-to-reach scenarios of the RBC of TACN according to claim 1, wherein an expression of the reward function R is shown in Equation (5):
$$R = {α}_{1} {r}_{1} - {α}_{2} {r}_{2} + {α}_{3} {r}_{3} , \qquad ( 5 )$$
wherein r₁, r₂ and r₃ are a discovery reward, an exploration failure reward, and an irrational allocation reward, respectively, and α₁, α₂ and α₃ are weight coefficients of the rewards;
the discovery reward is configured to improve an exploration capability of the hard-to-reach scenario generator for the hard-to-reach scenarios, and an expression of the discovery reward is shown in Equation (6):
$${r}_{1} = \{ \begin{matrix}a , & route allocation error \\ 0 , & others\end{matrix} ; \qquad ( 6 )$$
the exploration failure reward is configured to indicate whether a hard-to-reach scenario occurs within a predetermined period, and an expression of the exploration failure reward is shown in Equation (7):
$${r}_{2} = \{ \begin{matrix}p , & exploration failure \\ 0 , & exploration success\end{matrix} ; \qquad ( 7 )$$
the irrational allocation reward is configured to indicate whether an irrational allocation occurs within a predetermined period, and an expression of the irrational allocation reward is shown in Equation (8):
$${r}_{3} = \{ \begin{matrix}- q , & irrational allocation \\ q , & rational allocation\end{matrix} . \qquad ( 8 )$$

8. The reinforced generation method for the hard-to-reach scenarios of the RBC of TACN according to claim 1, wherein
the loss function=the maximum Q value of the target neural network in the Sₜ₊₁ status+the reward value rₜ of the Q neural network in an Sₜ status−the Q value of the Q neural network in the Sₜ status.

9. The reinforced generation method for the hard-to-reach scenarios of the RBC of TACN according to claim 1, wherein the Q value deviation Δθ is as follows:
$$Δ θ = α [ {y}_{c} - Q ( {S}_{t} , ac ; θ ) ] ∇ Q ( S , AC ; θ ) ,$$
wherein α is a deep learning rate, S,AC represent a discrete event dynamic system status set and a set of selected action information, respectively, and yₜ is the reward value of the target neural network in the Sₜ₊₁ status.

10. The reinforced generation method for the hard-to-reach scenarios of the RBC of TACN according to claim 9, wherein the reward value yₜ of the target neural network in the Sₜ₊₁ status is as follows:
if a current status Sₜ is the terminal status, yₜ=rₜ, otherwise, yₜ=the maximum Q value of the target neural network in the Sₜ₊₁ status+rₜ, i.e.
$${y}_{t} = {r}_{t} + γ Q ( {S}_{t + 1} , arg {max}_{ac} Q ( {S}_{t} , ac ; θ ) ; {θ}^{-} ) ,$$
wherein γ is a discount factor.

11. The reinforced generation method for the hard-to-reach scenarios of the RBC of TACN according to claim 1, wherein
if the Sₜ₊₁ status is not the terminal status, a quadruple {Sₜ, ac, rₜ, Sₜ₊₁} is stored in an experience replay buffer, and the Q neural network selects a plurality of quadruples from the experience replay buffer for training; and the target neural network selects a plurality of quadruples from the experience replay buffer for training.

12. The reinforced generation method for the hard-to-reach scenarios of the RBC of TACN according to claim 1, wherein the updating the target neural network parameter θ⁻ comprises:
copying the network parameter θ of the Q neural network to the target neural network to enable θ⁻=θ.

13. The reinforced generation method for the hard-to-reach scenarios of the RBC of TACN according to claim 1, wherein
the Q neural network is a fully connected network, wherein a ReLU activation function is adopted among fully connected layers thereof; and the Q neural network provides a bounded output by a tanh activation function.

14. The reinforced generation method for the hard-to-reach scenarios of the RBC of TACN according to claim 1, wherein
the target neural network and the Q neural network are the same in structure.

15. The reinforced generation method for the hard-to-reach scenarios of the RBC of TACN according to claim 1, wherein the first preset condition comprises:
a number of training iterations reaching a first preset number;
and/or a duration of the training cycle reaching a first preset duration;
and/or a train entering an incorrect route.

16. The reinforced generation method for the hard-to-reach scenarios of the RBC of TACN according to claim 1, wherein the second preset condition comprises:
a number of training iterations reaching a second preset number.

17. A reinforced generation system for hard-to-reach scenarios of a radio block center (RBC) of train autonomous circulation and navigation (TACN), comprising:
the hard-to-reach scenario generator generated by adopting the reinforced generation method for the hard-to-reach scenarios of the RBC of TACN according to claim 1; and
the discrete event dynamic system, in communication connection to the hard-to-reach scenario generator.

18. A radio block center (RBC) test system, comprising:
using the hard-to-reach scenario generator generated by adopting the reinforced generation method for the hard-to-reach scenarios of the RBC of TACN according to claim 1.
